(19) United States
(12) Patent Application Publication
(10) Pub. No.: US 2024/0405058 A1
(43) Pub. Date: Dec. 5, 2024

(54) DISPLAY DEVICE, FLEXIBLE DISPLAY DEVICE, AND METHOD OF MANUFACTURING DISPLAY DEVICE

(71) Applicant: Samsung Display Co., LTD., Yongin-si (KR)

(72) Inventors: Seung Min LEE, Yongin-si (KR); Young Ji KIM, Yongin-si (KR); Hyun KIM, Yongin-si (KR); Je Won YOO, Yongin-si (KR)

(21) Appl. No.: 18/585,289

(22) Filed: Feb. 23, 2024

(30) Foreign Application Priority Data
May 31, 2023 (KR) 10-2023-0070190

(51) Int. Cl. H01L 27/15

(52) U.S. Cl. CPC H01L 27/156

(57) ABSTRACT

According to an embodiment of the disclosure, a display device includes: a substrate layer including a substrate defining a hole therein and an organic layer of which at least a portion is disposed in the hole, and a display layer on the substrate layer. The hole passes through the substrate, and the organic layer contacts at least a portion of the display layer.

The application claims priority to Korean patent application No. 10-2023-0070190, filed on May 31, 2023, and all the benefits accruing therefrom under 35 U.S.C. § 119, the content of which in its entirety is herein incorporated by reference.

### BACKGROUND

### 1. Field

The disclosure relates to a display device, a flexible display device, and a method of manufacturing the display device.

### 2. Description of the Related Art

Research on a flexible display device is being actively conducted. Since the flexible display device may be manufactured in various forms, the flexible display device may have an advantage that a design freedom degree is high, aesthetics is improved, a display screen of a relatively large area may be implemented, and the flexible display device is suitably applicable to various fields.

In order for the flexible display device to operate normally, a panel forming the flexible display device is required to have a flexible characteristic including a bendable characteristic, a rollable characteristic, or the like.

In order for the panel to have the flexible characteristic, a structure in which a patterned lattice structure or the like is formed in a partial area is discussed. However, as an additional structure for imparting the flexible characteristic to the display device is included, a risk of damage to structural stability may occur.

### SUMMARY

An aspect of the disclosure is to provide a display device, a flexible display device, and a method of manufacturing the display device with improved structural stability of a panel.

An aspect of the disclosure is to provide a display device, a flexible display device, and a method of manufacturing the display device with simplified a process step.

An aspect of the disclosure is to provide a flexible display device that is robust against an external influence, and a method of manufacturing a display device.

According to an embodiment of the disclosure, a display device includes: a substrate layer including a substrate defining a hole therein and an organic layer of which at least a portion is disposed in the hole, and a display layer on the substrate layer. The hole passes through the substrate, and the organic layer may contact at least a portion of the display layer.

According to an embodiment, the display device may be folded or bent along a bending line. The display device may include a display area for emitting light and overlapping the bending line. The bending line may overlap the organic layer in a plan view.

According to an embodiment, the substrate may have a first thickness. The organic layer may have a second thickness larger than the first thickness.

According to an embodiment, the organic layer may include a tapered surface extending in an oblique direction with respect to a plane on which the substrate layer is disposed. An angle formed by the tapered surface and the display layer may be equal to or more than 60 degrees and less than 90 degrees.

According to an embodiment, the substrate layer may include a first surface adjacent to the display layer and a second surface opposite to the first surface. The organic layer may include a first cross-section cut by the first surface and having a first cross-sectional area and a second cross-section cut by the second surface and having a second cross-sectional area larger than the first cross-sectional area.

According to an embodiment, the display layer may include a lowermost insulating layer directly adjacent to the substrate layer. The organic layer and the lowermost insulating layer may contact each other in an area where the hole is formed.

According to an embodiment, the display layer may include a pixel circuit including a transistor and a light emitting element electrically connected to the pixel circuit. The transistor may include an active layer, a gate electrode overlapping the active layer in a plan view, a source electrode electrically connected to a first contact area of the active layer, and a drain electrode electrically connected to a second contact area of the active layer. The lowermost insulating layer may be a buffer layer directly adjacent to a lower portion of the active layer.

According to an embodiment, the organic layer may include an undercut area formed in an area adjacent to both the lowermost insulating layer and the substrate. In the undercut area, the organic layer may contact the lowermost insulating layer, and may contact the substrate.

According to an embodiment, in the undercut area, the substrate and the lowermost insulating layer may form an angle of less than 15 degrees.

According to an embodiment, the display device may include a display area and a non-display area surrounding at least a portion of the display area, and a driving chip. The display layer may include a pixel circuit electrically connected to the driving chip. The substrate may include a first substrate and a second substrate disposed on a rear surface of the first substrate in the non-display area. The driving chip may be disposed on the rear surface of the first substrate. The substrate may define an outer hole between an end of the first substrate and an end of the second substrate.

According to an embodiment, the second substrate may not overlap the organic layer in a plan view.

According to an embodiment, the display device may further include an outer organic layer provided in the outer hole.

According to an embodiment, the substrate may include a glass material. The organic layer may include one or more of a group of polyurethane, polyimide, polyethylene, and polypropylene.

According to an embodiment, the display device may further include an upper layer disposed on the display layer and including a window, and a lower layer disposed under the substrate layer and including a sensing module.

According to an embodiment of the disclosure, a flexible display device is folded or bent along a bending line. The flexible display device includes a display area and a non-display area surrounding at least a portion of the display area, a substrate layer including a first substrate defining a first hole therein, a second substrate disposed on a rear surface of the first substrate, and an organic layer of which at least a portion is disposed in the first hole, and a display layer disposed on the substrate layer and including a light emitting element disposed in the display area. The organic layer overlaps the bending line in a plan view. The first substrate and the second substrate overlap in the plan view in the non-display area. Ends of the first substrate and the second substrate are spaced apart from each other to form a second hole.

According to an embodiment of the disclosure, a method of manufacturing a display device may include disposing a display layer on a first surface of a substrate including the first surface and a second surface opposite to the first surface, forming a hole passing through the substrate by performing wet etching on at least a portion of the substrate in a direction from the second surface toward the first surface, and disposing an organic layer in the hole.

According to an embodiment, the display layer may include a lowermost insulating layer. Forming the hole may include exposing the lowermost insulating layer. Disposing the organic layer may include contacting the lowermost insulating layer and the organic layer.

According to an embodiment, forming the hole may include forming a free-hole structure by performing a laser process on the substrate before the wet etching.

According to an embodiment, the method may further include disposing a driving circuit unit including a driving chip on the first surface of the substrate, forming an outer hole passing through the substrate to provide a first substrate and a second substrate spaced apart from each other, as a step performed in a same process as forming the hole, and folding a stack structure including the first substrate and the second substrate along an outer folding line overlapping the outer hole.

According to an embodiment, the method may further include disposing an outer organic layer in the outer hole.

According to an embodiment of the disclosure, a display device, a flexible display device, and a method of manufacturing the display device with improved structural stability of a panel may be provided.

According to an embodiment of the disclosure, a display device, a flexible display device, and a method of manufacturing the display device with simplified a process step may be provided.

According to an embodiment of the disclosure, a display device and a flexible display device robust against an external influence, and a method of manufacturing the display device may be provided.

### BRIEF DESCRIPTION OF THE DRAWINGS

The above and other features of the disclosure will become more apparent by describing in further detail embodiments thereof with reference to the accompanying drawings, in which:

FIGS. 1 and 2 are schematic plan views illustrating a display device according to an embodiment;

FIGS. 3 and 4 are schematic cross-sectional views illustrating a display device according to an embodiment;

FIG. 5 is a schematic cross-sectional view illustrating a display device according to an embodiment;

FIG. 6 is a schematic enlarged view of an EA1 area of FIG. 5;

FIGS. 7 and 8 are schematic cross-sectional views illustrating a display device according to an embodiment; and

FIGS. 9 to 17 are schematic cross-sectional views for each process step illustrating a method of manufacturing the display device 1 according to an embodiment.

### DETAILED DESCRIPTION OF THE EMBODIMENT

The disclosure may be modified in various manners and have various forms. Therefore, specific embodiments will be illustrated in the drawings and will be described in detail in the specification. However, it should be understood that the disclosure is not intended to be limited to the disclosed specific forms, and the disclosure includes all modifications, equivalents, and substitutions within the spirit and technical scope of the disclosure.

Terms of “first”, “second”, and the like may be used to describe various components, but the components should not be limited by the terms. The terms are used only for the purpose of distinguishing one component from another component. For example, without departing from the scope of the disclosure, a first component may be referred to as a second component, and similarly, a second component may also be referred to as a first component. In the following description, the singular expressions include plural expressions unless the context clearly dictates otherwise.

It should be understood that in the present application, a term of “include”, “have”, or the like is used to specify that there is a feature, a number, a step, an operation, a component, a part, or a combination thereof described in the specification, but does not exclude a possibility of the presence or addition of one or more other features, numbers, steps, operations, components, parts, or combinations thereof in advance. In addition, a case where a portion of a layer, a layer, an area, a plate, or the like is referred to as being “on” another portion, it includes not only a case where the portion is “directly on” another portion, but also a case where there is further another portion between the portion and another portion. In addition, in the present specification, when a portion of a layer, a layer, an area, a plate, or the like is formed on another portion, a forming direction is not limited to an upper direction but includes forming the portion on a side surface or in a lower direction. On the contrary, when a portion of a layer, a layer, an area, a plate, or the like is formed “under” another portion, this includes not only a case where the portion is “directly beneath” another portion but also a case where there is further another portion between the portion and another portion.

The disclosure relates to a display device, a flexible display device, and a method of manufacturing the display device.

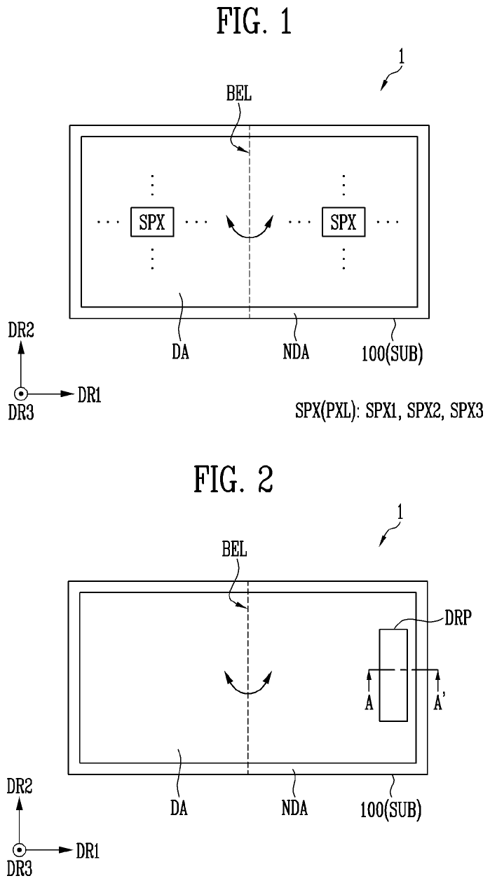

First, a display device 1 according to an embodiment is described with reference to FIGS. 1 to 8.

FIGS. 1 and 2 are schematic plan views illustrating a display device according to an embodiment. As used herein, the “plan view” is a view in a thickness direction (i.e., DR3) of the display device in an unfolded state of the display device.

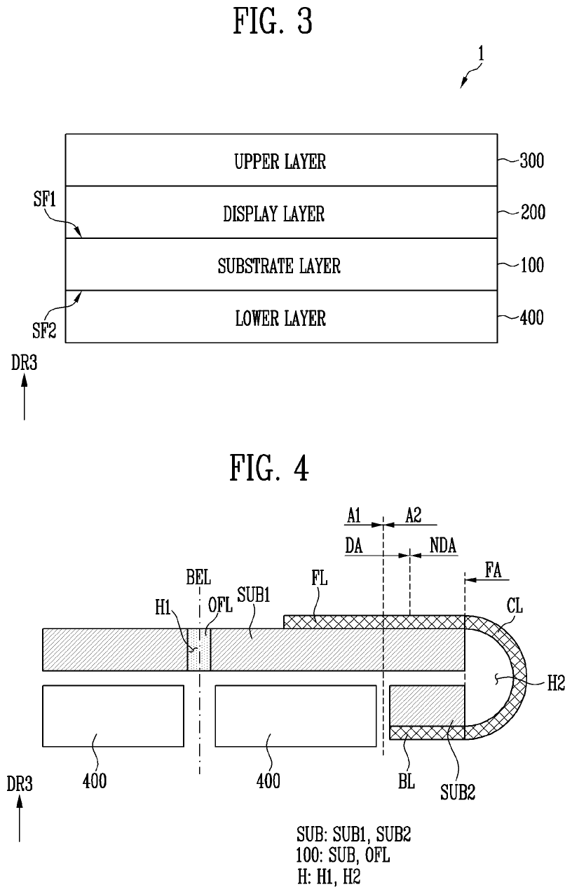

Referring to FIGS. 1 and 2, the display device 1 is configured to emit light. The display device 1 may include a light emitting element LD (refer to FIG. 3). The display device 1 may be applied to various fields, and an example thereof is not particularly limited.

The display device 1 may be a flexible display device in which at least a portion thereof may be bent or deformed. For example, the display device 1 may be one or more of a rollable display device, a bendable display device, a curved display device, and a foldable display device.

According to an embodiment, the display device 1 may be folded or bent with respect to a bending line BEL. The bending line BEL may be a virtual axis parallel to the second direction DR2. According to an embodiment, the bending line BEL may extend on a second direction DR2. A position and the number of bending lines BEL are not particularly limited. For example, a plurality of bending lines BEL may be provided and respectively formed at two or more spaced apart positions in the display device 1. In addition, when the display device 1 is a rollable display device, the bending line BEL may be at least a partial line or area included in a rolled area.

A direction in which the display device 1 is bent is not particularly limited. For example, in the display device 1, a display area DA where time information is output may be bent to face an inner side. According to an embodiment, the display area DA may be bent to face an outer side.

The display device 1 may include a substrate layer 100 and a sub-pixel SPX disposed (or formed) on the substrate layer 100. A plurality of sub-pixels SPX may be provided to form one or more pixels PXL. The display device 1 may further include a driving circuit unit DRP.

The display device 1 may include the display area DA and a non-display area NDA. The non-display area NDA may mean an area other than the display area DA. The non-display area NDA may surround at least a portion of the display area DA.

The substrate layer 100 may form a base member of the display device 1. The substrate layer 100 may include a substrate SUB including a hard material. For example, the substrate layer 100 may include a substrate SUB including glass (or tempered glass).

The display area DA may refer to an area where the sub-pixel SPX (or the light emitting element LD) is disposed. The non-display area NDA may refer to an area in which the sub-pixel SPX is not disposed. According to an embodiment, the non-display area NDA may include an outer folding area FA (refer to FIG. 4).

A line, a pad, and the like electrically connected to the sub-pixel SPX may be disposed in the non-display area NDA. For example, a front surface signal line FL (refer to FIG. 4), a connection line CL (refer to FIG. 4), and a rear surface signal line BL (refer to FIG. 4) may be disposed in the non-display area NDA. Scan lines and data lines may be disposed in the non-display area NDA.

According to an embodiment, the pixel PXL (or the sub-pixels SPX) may include a first sub-pixel SPX1, a second sub-pixel SPX2, and a third sub-pixel SPX3. According to an embodiment, the first sub-pixel SPX1, the second sub-pixel SPX2, and the third sub-pixel SPX3 may be arranged according to various arrangement structures. For example, the first sub-pixel SPX1, the second sub-pixel SPX2, and the third sub-pixel SPX3 may be arranged according to a stripe or a PENTILE™ arrangement structure, or the like. However, the disclosure is not limited thereto.

One or more of the first sub-pixel SPX1, the second sub-pixel SPX2, and the third sub-pixel SPX3 may form a pixel unit. For example, each of the first sub-pixel SPX1, the second sub-pixel SPX2, and the third sub-pixel SPX3 may emit light of one color. For example, the first sub-pixel SPX1 may be a green pixel for emitting light of green (for example, first color), the second sub-pixel SPX2 may a red pixel for emitting light of red (for example, second color), and the third sub-pixel SPX3 may be a blue pixel for emitting light of blue (for example, third color).

The driving circuit unit DRP may be disposed on a rear surface of the substrate layer 100. The driving circuit unit DRP may be disposed on the rear surface of the substrate layer 100 and electrically connected to the pixel PXL on a front surface of the substrate layer 100 through various lines and/or contact structures.

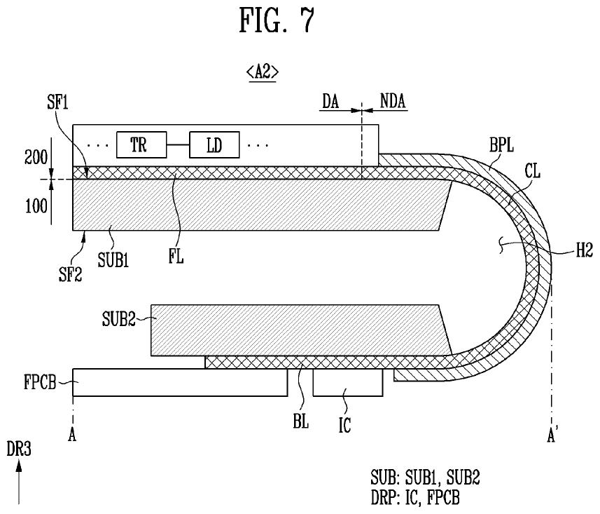

The driving circuit unit DRP may include a driving chip IC (refer to FIG. 7) and a circuit board FPCB (refer to FIG. 7). The driving chip IC and the circuit board FPCB may be electrically connected to each other. The driving chip IC may be disposed on the first surface of the second substrate SUB2. In FIG. 7, it is illustrated that the first surface of the second substrate SUB2 faces a direction (e.g., downward) opposite to the direction (e.g., upward) the first surface of the first substrate SUB1 faces.

The driving chip IC may include a scan driver electrically connected to the scan lines to supply a scan signal. According to an embodiment, the driving chip IC may include a data driver electrically connected to the data lines to supply a data signal.

The driving circuit unit DRP may be disposed on the rear surface of the substrate layer 100, and thus a range of a dead space may be reduced. According to an embodiment, the driving circuit unit DRP may overlap the non-display area NDA in a plan view. According to an embodiment, at least a portion of the driving circuit unit DRP may overlap the display area DA in a plan view.

In the present specification, a “plane” may mean a plane on which the substrate layer 100 is disposed. For example, the plane may extend in a first direction DR1 and may extend in the second direction DR2. A normal direction of the plane may be a third direction DR3, which is perpendicular to the plane.

Next, a cross-sectional structure of the display device 1 according to an embodiment is described with reference to FIGS. 3 and 4.

FIGS. 3 and 4 are schematic cross-sectional views illustrating a display device according to an embodiment. FIG. 3 shows a plurality of layers included in the display device 1 according to an embodiment. FIG. 4 shows a first area A1 and a second area A2 as at least some areas of the display device 1 according to an embodiment.

The first area A1 may include an inner area of the display device 1. For example, the first area A1 may be included in the display area DA. The second area A2 may include an edge area of the display device 1. For example, the second area A2 may include the entirety of the non-display area NDA, and the second area A2 may include a partial area of the display area DA adjacent to the non-display area NDA.

Referring to FIGS. 3 and 4, the display device 1 includes the substrate layer 100 and a display layer 200. The display device 1 may further include an upper layer 300 and a lower layer 400. The display device 1 according to an embodiment may include the first area A1 and/or the second area A2. For example, the display device 1 may include both of the first area A1 and the second area A2. Meanwhile, although the display device 1 is shown as including the first area A1 and the second area A2 in FIG. 4, the display device 1 may include only the first area A1 (for example, a technical feature of the first area A1), or the display device 1 may include only the second area A2 (for example, a technical feature of the second area A2) in another embodiment.

The substrate layer 100 may include a first surface SF1 on which the display layer 200 is disposed and a second surface SF2 on which the lower layer 400 is disposed. In the present specification, a front surface of the display device 1 may correspond to the first surface SF1. A rear surface of the display device 1 may correspond to the second surface SF2. The first surface SF1 or the second surface SF2 is referred to as a “major surface” of the substrate layer 100.

The substrate layer 100 may include the substrate SUB and an organic layer OFL.

The substrate SUB may include a hard material. The substrate SUB may include (or define) a hole H. According to an embodiment, the organic layer OFL may be provided in at least a portion of the hole H.

The substrate SUB may include a first substrate SUB1 and a second substrate SUB2. The first substrate SUB1 and the second substrate SUB2 may overlap each other in a plan view. The first substrate SUB1 and the second substrate SUB2 may not overlap each other in a planar direction. As used herein, the “planar direction” is a direction parallel to the plane defined by the first direction DR1 and second direction DR2. In other words, the “planar direction” is a direction perpendicular to the thickness direction in the unfolded state of the display device 1.

The first substrate SUB1 may be disposed across the first area A1 and the second area A2, and the second substrate SUB2 may be disposed in the second area A2 without being disposed in the first area A1. For example, the second substrate SUB2 may not overlap the organic layer OFL and a first hole H1 in a plan view.

The front surface signal line FL may be disposed on the first substrate SUB1. The rear surface signal line BL may be disposed on the second substrate SUB2. The front surface signal line FL and the rear surface signal line BL may be electrically connected by the connection line CL disposed in the outer folding area FA. However, the disclosure is not limited thereto. For another example, the front surface signal line FL and the rear surface signal line BL may be electrically connected by a contact structure (e.g., wire) passing through both the first substrate SUB1 and the second substrate SUB2.

The front surface signal line FL, the rear surface signal line BL, and the connection line CL may be formed in a same process, and may be electrically connected to each other. The connection line CL may be a side surface signal line folded when the substrate layer 100 is manufactured.

The substrate SUB may define the hole H therein. According to an embodiment, the hole H may be manufactured by removing at least a portion of a glass material layer forming the substrate.

The hole H may include the first hole H1 and a second hole H2. The first hole H1 may be defined by the first substrate SUB1. The first hole H1 may be included in the first substrate SUB1. The second hole H2 may be defined by first substrate SUB1 and the second substrate SUB2. According to an embodiment, the second hole H2 may be referred to as an “outer hole”.

The first hole H1 may be disposed in the first area A1 (or the display area DA). The second hole H2 may be disposed in the second area A2 (or the non-display area NDA).

According to an embodiment, the second hole H2 may be formed in the outer folding area FA (for example, a side surface area). The second hole H2 may be directly adjacent to an end of the first substrate SUB1 and an end of the second substrate SUB2. The end of the first substrate SUB1 and the end of the second substrate SUB2 may be spaced apart from each other to form the second hole H2.

The organic layer OFL may be disposed in the first area A1 and may be disposed in the display area DA. The organic layer OFL may not overlap the second substrate SUB2 in a plan view, and at least a portion of the organic layer OFL may not overlap the first substrate SUB1 in a plan view.

The organic layer OFL may be disposed in the hole H. For example, the organic layer OFL may be disposed in the first hole H1. The organic layer OFL may be disposed or may not be disposed in the second hole H2. At least a portion of the organic layer OFL may not overlap a sensing module (for example, a digitizer module) of the lower layer 400 in a plan view.

The display layer 200 may be disposed on the first surface SF1 of the substrate layer 100. The display layer 200 may be implemented by various types of light sources (for example, the light emitting element LD). For example, the light emitting element LD included in the display layer 200 may include an inorganic light emitting element (for example, a micro LED or a nano LED) including an inorganic semiconductor or an organic light emitting diode (“OLED”). However, the disclosure is not particularly limited.

The upper layer 300 may be disposed on the display layer 200. The upper layer 300 may be generally disposed outside the display device 1 to protect internal configurations. According to an embodiment, the upper layer 300 may include a cover member (for example, a window) capable of transmitting light. According to an embodiment, the upper layer 300 may include one of a polyethyleneterephthalate (“PET”) film, a low reflection film, a polarizing film, and a transmittance controllable film. A structure of the upper layer 300 is not limited to a special example.

The lower layer 400 may be disposed on the second surface SF2 of the substrate layer 100. For example, the lower layer 400 may be disposed on the second surface SF2 that is a rear surface of the first substrate SUB1.

The lower layer 400 may be disposed adjacent to a rear surface side of the display device 1 and may include various functional layers. According to an embodiment, the lower layer 400 may include a sensing unit. For example, the sensing unit may include a digitizer module. According to an embodiment, the digitizer module may include a first sensing electrode, a second sensing electrode, and an insulating layer disposed between the first sensing electrode and the second sensing electrode. According to an embodiment, the digitizer module may receive an input of an electronic pen configured to interact with the display device 1. According to an embodiment, the lower layer 400 may include a cushion layer. A cushioning unit may include various materials having a cushion property. For example, the cushion unit may include at least one of a group of latex, sponge, urethane foam which is an expandable resin, EVA, and the like. A structure of the lower layer 400 is not limited to the above-described example. For example, the lower layer 400 may further include a heat dissipation member including graphite.

According to an embodiment, the lower layer 400 may be disposed in the first area A1. The lower layer 400 may overlap the display area DA in a plan view. For example, the lower layer 400 may overlap the first substrate SUB1 and may not overlap the second substrate SUB2 in a plan view.

According to an embodiment, the lower layer 400 may not overlap at least a portion of the organic layer OFL in a plan view. Accordingly, the bending line BEL may be defined at a position corresponding to an area where the organic layer OFL is disposed in another embodiment.

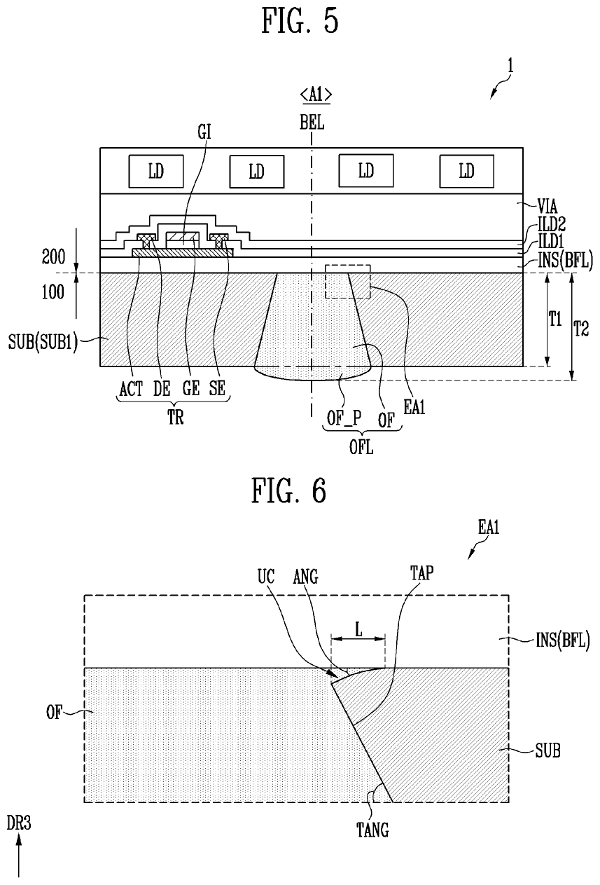

Next, a cross-sectional structure of the display device 1 in the first area A1 is described with reference to FIGS. 5 and 6.

FIG. 5 is a schematic cross-sectional view illustrating a display device according to an embodiment. FIG. 5 is a schematic cross-sectional view illustrating the display device 1 in the first area A1 based on the substrate layer 100 and the display layer 200. FIG. 6 is a schematic enlarged view of an EA1 area of FIG. 5. FIG. 6 schematically shows an area where the substrate layer 100 and the display layer 200 are directly adjacent. According to an embodiment, the substrate SUB shown in FIGS. 5 and 6 may be the first substrate SUB1. For convenience of description, the disclosure is described based on the “substrate SUB”.

According to an embodiment, the organic layer OFL may include an organic material. According to an embodiment, the organic material may include at least one of a group of polyurethane, polyimide, polyethylene, and polypropylene. However, the organic material for forming the organic layer OFL is not particularly limited.

The organic layer OFL may have a relatively high restoring characteristic. For example, the organic layer OFL may overlap the bending line BEL in a plan view. Accordingly, a flexible characteristic in which a pose of the display device 1 may be suitably changed based on the bending line BEL may be secured.

The organic layer OFL may include a body organic layer OF and a protrusion organic layer OF_P. The body organic layer OF and the protrusion organic layer OF_P may be integrally formed. The body organic layer OF may contact an inner surface of the substrate SUB. The protrusion organic layer OF_P may protrude from the body organic layer OF.

According to an embodiment, the organic layer OFL may have a thickness thicker than the substrate SUB. For example, the substrate SUB may have a first thickness T1. The organic layer OFL may have a second thickness T2 larger than the first thickness T1. Accordingly, a portion of the organic layer OFL may have a structure protruding with respect to the substrate SUB, and stress may be relieved when the display device 1 is folded with respect to the bending line BEL.

According to an embodiment, as the organic layer OFL is disposed, the display device 1 may be protected from dust, moisture, and the like that may be introduced from an outside.

According to an embodiment, each of the organic layer OFL and the substrate SUB may include a tapered surface TAP. For example, the tapered surface TAP may extend in an oblique direction with respect to a major surface of the substrate layer 100. According to an embodiment, the tapered surface TAP may form a tapered angle TANG with respect to a direction in which the display layer 200 extends (i.e., major surface of the display layer 200). According to an embodiment, the tapered angle TANG may be 60 degrees or more. According to an embodiment, the tapered angle TANG may be larger than or equal to 60 degrees and less than 90 degrees.

The body organic layer OF may include a first surface having a first cross-sectional area on the first surface SF1 of the substrate layer 100, and the body organic layer OF may include a second surface SF2 having a second cross-sectional area on the second surface SF2 of the substrate layer 100. According to an embodiment, the first cross-sectional area may be less than the second cross-sectional area in a plan view. That is, the cross-section of the organic layer OFL may decrease in a direction from the second surface SF2 toward the first surface SF1.

The organic layer OFL may directly adjacent to the substrate SUB. The organic layer OFL and the substrate SUB may contact each other.

According to an embodiment, the organic layer OFL may include an undercut area UC. For example, the body organic layer OF may include an undercut area UC formed in an area adjacent to both a lowermost insulating layer INS and the substrate SUB.

The undercut area UC may be formed by over-etching the substrate SUB in an area where the substrate SUB is directly adjacent to the display layer 200 when the substrate SUB is etched to form an area where the organic layer OFL is disposed. In the undercut area UC, the organic layer OFL may contact the substrate SUB and may contact the lowermost insulating layer INS.

In the undercut area UC, the substrate SUB and the lowermost insulating layer INS may be spaced apart from each other, and in the undercut area UC, a portion of the substrate SUB and the lowermost insulating layer INS may form an angle ANG. According to an embodiment, the angle ANG may be less than 15 degrees. According to an embodiment, a length L of the undercut area UC in the planar direction may be 100 micrometers (μm) or less. However, the disclosure is not necessarily limited thereto.

As described above, the organic layer OFL may function as an adhesive layer between the substrate SUB and the display layer 200. As the undercut area UC is formed, a contact area of the organic layer OFL between the substrate SUB and the display layer 200 may be expanded, and adhesion performance may be further improved.

According to an embodiment, the organic layer OFL may contact the display layer 200. For example, the organic layer OFL may contact the lowermost insulating layer INS of the display layer 200. The body organic layer OF may contact the lowermost insulating layer INS. The lowermost insulating layer INS may be a buffer layer BFL. For example, the lowermost insulating layer INS may be a buffer structure directly adjacent to a lower portion of the buffer layer BFL. The organic layer OFL may contact the buffer layer BFL. However, the disclosure is not limited thereto. For another example, the lowermost insulating layer INS may be one selected from insulating layers disposed in the display layer 200.

According to an embodiment, as the organic layer OFL and the display layer 200 are directly adjacent to each other, the substrate layer 100 and the display layer 200 may be coupled to each other (e.g., contact). For example, the organic layer OFL may contact the lowermost insulating layer INS and function as an adhesive layer. Accordingly, a separate process for disposing an adhesive layer may not be required.

The display layer 200 may include the lowermost insulating layer INS directly adjacent to (e.g., contact) the first surface SF1 of the substrate layer 100.

The display layer 200 may include a pixel circuit and the light emitting element LD electrically connected to the pixel circuit. The pixel circuit may include a transistor TR. The transistor TR may include a driving transistor. According to an embodiment, the pixel circuit may further include a switching transistor, a capacitor, and the like.

The display layer 200 may include the lowermost insulating layer INS, the transistor TR, a first interlayer insulating layer ILD1, a gate insulating layer GI, a second interlayer insulating layer ILD2, and a via-layer VIA.

The lowermost insulating layer INS may be disposed on a lowermost portion of the display layer 200. As described above, the lowermost insulating layer INS may be the buffer layer BFL. However, the disclosure is not limited thereto, and the lowermost insulating layer INS may be the first interlayer insulating layer ILD1 or the second interlayer insulating layer ILD2.

According to an embodiment, the lowermost insulating layer INS may include an inorganic material. For example, the lowermost insulating layer INS may include at least one of a group of amorphous silicon (a-Si), silicon oxide (SiOx), silicon nitride (SiNx), and silicon oxynitride (SiOxNy). However, the disclosure is not necessarily limited thereto. According to an embodiment, the lowermost insulating layer INS may include an organic material. For example, the lowermost insulating layer INS may include polyimide.

According to an embodiment, the transistor TR may not overlap the bending line BEL in a plan view. The transistor TR may include an active layer ACT, a gate electrode GE, a drain electrode DE, and a source electrode SE.

The active layer ACT may be disposed on the lowermost insulating layer INS. According to an embodiment, the active layer ACT may include at least one of a group of polysilicon, low temperature polycrystalline silicon (“LTPS”), amorphous silicon, and an oxide semiconductor. The active layer ACT may include a first contact area contacting the source electrode SE and a second contact area contacting the drain electrode DE. The first contact area and the second contact area may be a semiconductor pattern doped with an impurity. An area between the first contact area and the second contact area may be a channel area. The channel area may be an intrinsic semiconductor pattern which is not doped with an impurity.

The gate insulating layer GI may be disposed between the gate electrode GE and the active layer ACT. The gate insulating layer GI may include various inorganic materials.

The first interlayer insulating layer ILD1 may be disposed on the lowermost insulating layer INS. The first interlayer insulating layer ILD1 may cover the active layer ACT. The first interlayer insulating layer ILD1 may include an inorganic material.

The gate electrode GE may be disposed on the gate insulating layer GI and may be disposed on the channel area of the active layer ACT with the gate insulating layer GI interposed therebetween. The gate electrode GE may include a conductive material.

The source electrode SE and the drain electrode DE may be disposed on the first interlayer insulating layer ILD1. The source electrode SE may pass through the first interlayer insulating layer ILD1 to electrically contact the first contact area of the active layer ACT, and the drain electrode DE may pass through the first interlayer insulating layer ILD1 to electrically contact the second contact area of the active layer ACT. According to an embodiment, the source electrode SE or the drain electrode DE may be electrically connected to the light emitting element LD through one contact portion.

The second interlayer insulating layer ILD2 may be disposed on the first interlayer insulating layer ILD1. The second interlayer insulating layer ILD2 may cover the source electrode SE and the drain electrode DE. The second interlayer insulating layer ILD2 may include an inorganic material.

The via-layer VIA may be disposed on the second interlayer insulating layer ILD2. The via-layer VIA may be a planarization layer. According to an embodiment, the via-layer VIA may include an organic material.

According to an embodiment, a layer including the light emitting element LD may be disposed on the via-layer VIA. The via-layer VIA may not overlap the bending line BEL in a plan view.

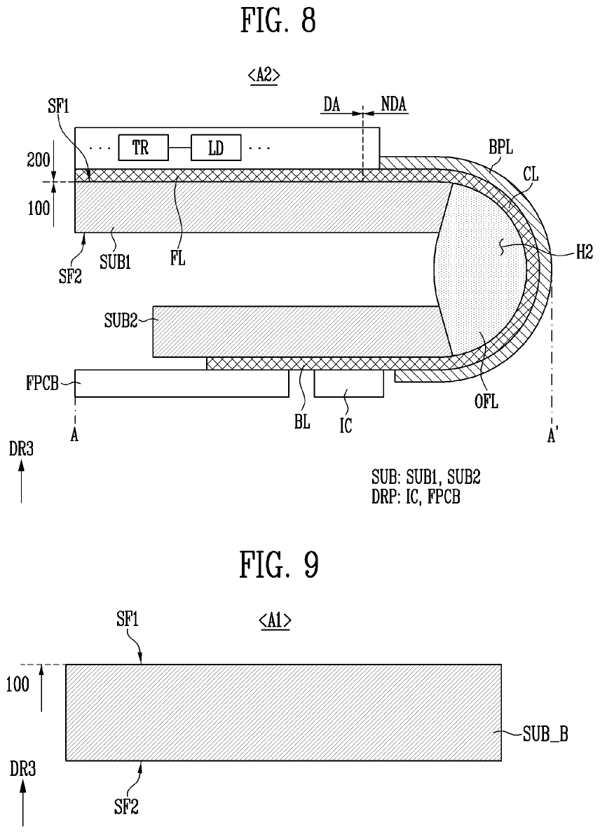

Next, a cross-sectional structure of the display device 1 in the second area A2 is described with reference to FIGS. 7 and 8.

FIGS. 7 and 8 are schematic cross-sectional views illustrating a display device according to an embodiment. FIGS. 7 and 8 are schematic cross-sectional views illustrating the display device 1 in the second area A2 based on the substrate layer 100 and the display layer 200. FIGS. 7 and 8 are schematic cross-sectional views taken along line A-A′ of FIG. 2.

According to an embodiment, the first substrate SUB1 and the second substrate SUB2 may overlap each other in a plan view.

The first substrate SUB1 may form an area where the display layer 200 disposed on the first surface SF1 may be disposed. For example, the front surface signal line FL may be disposed on the first substrate SUB1. Although not shown in the drawing, the front surface signal line FL may be electrically connected to the pixel circuit formed in the display layer 200. The front surface signal line FL may be disposed in a same layer as one or more of conductive layers disposed in the display layer 200.

The second substrate SUB2 may be disposed to be spaced apart from a lower portion of the first substrate SUB1 and may form an area where the driving circuit unit DRP may be disposed. According to an embodiment, the rear surface signal line BL may be disposed on the second substrate SUB2. The rear surface signal line BL may be disposed in a same layer as the front surface signal line FL. The rear surface signal line BL may be electrically connected to the driving chip IC and may be electrically connected to the circuit board FPCB.

According to an embodiment, the connection line CL may electrically connect the front surface signal line FL and the rear surface signal line BL, and may be covered by a protective layer BPL. The protective layer BPL may be disposed on the front surface signal line FL, the connection line CL, and the rear surface signal line BL to protect each of lines, and at least a portion thereof may be bent.

According to an embodiment, the second hole H2 may be formed between the first substrate SUB1 and the second substrate SUB2. For example, the second hole H2 may be formed in a same process as the first hole H1 described above. Accordingly, each of the first substrate SUB1 and the second substrate SUB2 may include an end including a tapered surface in the non-display area NDA.

According to an embodiment, the connection line CL and the protective layer BPL may be disposed on an area adjacent to the second hole H2. According to an embodiment, the organic layer OFL may not be disposed in the second hole H2 (FIG. 7). However, the disclosure is not limited thereto. For another example, the organic layer OFL may be disposed in the second hole H2 (FIG. 8).

In the present specification, the organic layer OFL in the first hole H1 may be referred to as a “first organic layer,” and the organic layer OFL in the second hole H2 may be referred to as a “second organic layer” or an “outer organic layer”.

According to an embodiment, after the second hole H2 defined between the first substrate SUB1 and the second substrate SUB2 is formed, a substrate structure may be folded, and thus a risk of stress occurring in the substrate layer 100 may be reduced.

Next, a method of manufacturing the display device 1 according to an embodiment is described with reference to FIGS. 9 to 17. A content that may overlap the above-described content is briefly described or is not repeated.

A method of manufacturing the display device 1 according to an embodiment may be a method of manufacturing a “flexible display device”.

FIGS. 9 to 17 are schematic cross-sectional views for each process step illustrating a method of manufacturing the display device 1 according to an embodiment.

FIGS. 9 to 12 schematically show a method of manufacturing the display device 1 based on the cross-sectional structure of the display device 1 in the first area A1. FIGS. 9 to 12 show the cross-sectional structure of FIG. 5 described above.

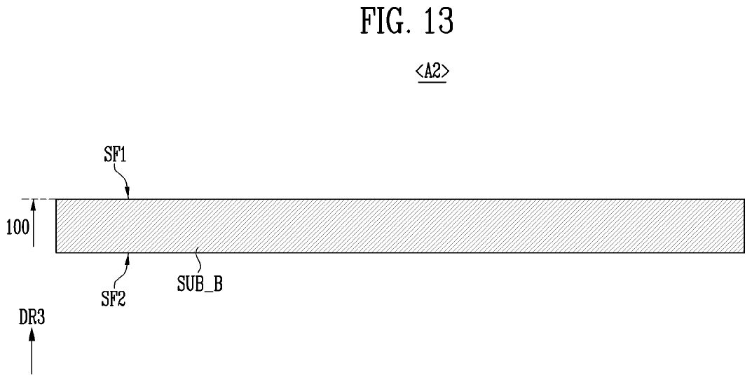

FIGS. 13 to 17 schematically show a method of manufacturing the display device 1 based on the cross-sectional structure of the display device 1 in the second area A2. FIGS. 13 to 17 show the cross-sectional structure of FIG. 7 or 8 described above.

Referring to FIGS. 9 and 13, a base substrate SUB_B may be prepared. The base substrate SUB_B may be a member for manufacturing the substrate layer 100 by forming the substrate SUB.

According to an embodiment, the base substrate SUB_B may include a glass material as described above. The base substrate SUB_B may be formed over the first area A1 and the second area A2.

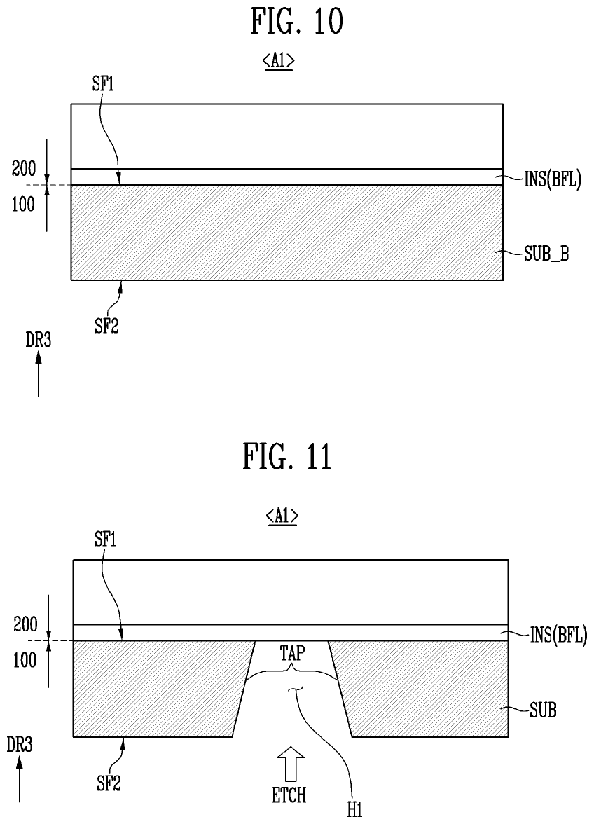

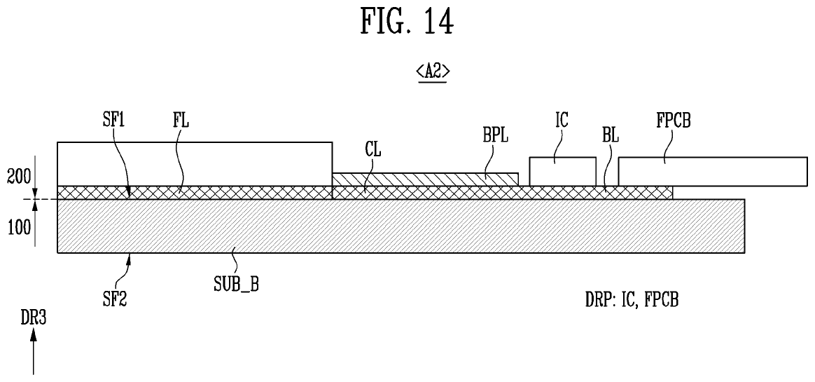

Referring to FIGS. 10 and 14, the display layer 200 and the driving circuit unit DRP may be formed on the base substrate SUB_B.

According to an embodiment, a process for patterning conductive layers and insulating layers on the base substrate SUB_B may be performed based on a general photolithography process, and an etching method, a deposition method, and the like are not limited to a specific example. In addition, the driving circuit unit DRP may also be attached by various known methods (adhesive layer or the like), and an example thereof is not particularly limited.

In the present step, when forming the display layer 200, the lowermost insulating layer INS may be patterned first. Accordingly, the lowermost insulating layer INS may directly adjacent to the base substrate SUB_B. Thereafter, conductive layers including a pixel circuit for forming the display layer 200, lines, and insulating layers may be patterned, and the light emitting element LD may be disposed. According to an embodiment, when the light emitting element LD includes an OLED, the light emitting element LD may be manufactured by sequentially depositing organic materials forming the light emitting element LD.

In the present step, a conductive layer for forming the front surface signal line FL, the connection line CL, and the rear surface signal line BL may be patterned on the base substrate SUB_B. In addition, the protective layer BPL may be patterned on the conductive layer, and an area where the protective layer BPL is patterned may include an area (for example, an outer folding line FOL) where substrate structures are bent in a subsequent process.

In the present step, the driving chip IC and the circuit board FPCB may be disposed on a conductive layer corresponding to the rear surface signal line BL. The driving chip IC and the circuit board FPCB may be electrically connected to each other.

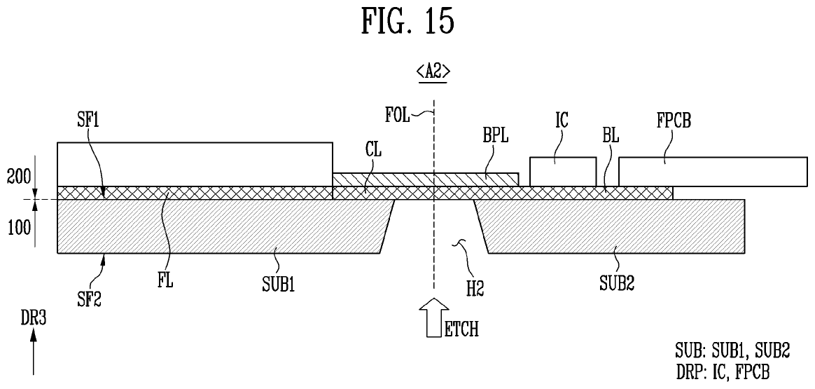

Referring to FIGS. 11 and 15, the substrate SUB including the hole H may be manufactured by removing at least a portion of the base substrate SUB_B.

In the first area A1, the base substrate SUB_B may be etched to form the first hole H1. In the present step, an etching process for forming the first hole H1 may be performed until the lowermost insulating layer INS is exposed. The first hole H1 may pass through the substrate SUB. In the present step, the exposed lowermost insulating layer INS may be the buffer layer BFL adjacent to the active layer ACT.

According to an embodiment, a wet etching process for the base substrate SUB_B may be performed in a direction from the second surface SF2 toward the first surface SF1. Accordingly, in the present step, the lowermost insulating layer INS may be exposed, and the tapered surface TAP may be formed in an area where the first hole H1 is formed. In addition, although not shown in FIG. 11, an undercut structure may be formed between the substrate SUB and the lowermost insulating layer INS.

In the second area A2, the base substrate SUB_B may be etched to form the second hole H2. In the present step, the second hole H2 may overlap the protective layer BPL and may overlap a conductive portion where the connection line CL is disposed. According to an embodiment, in the second area A2, an area where the base substrate SUB_B is etched may not overlap the driving circuit unit DRP. As the second hole H2 is formed, the first substrate SUB1 and the second substrate SUB2 spaced apart from each other may be manufactured. The first substrate SUB1 and the second substrate SUB2 may be adjacent to each other with the second hole H2 interposed therebetween. An area where the second hole H2 is formed may include an area (for example, the outer folding line FOL) where the substrate structures are bent in a subsequent process.

According to an embodiment, the etching process performed in the present step may include a wet etching process. In this case, the base substrate SUB_B including a glass material may be appropriately etched. According to an embodiment, the etching process performed in the present step may be performed after forming a free-hole structure by performing a laser process on the base substrate SUB_B. For example, the “free-hole structure” may be a structure for improving efficiency of a subsequent wet etching process by removing at least a portion of the base substrate SUB_B before all holes H are formed.

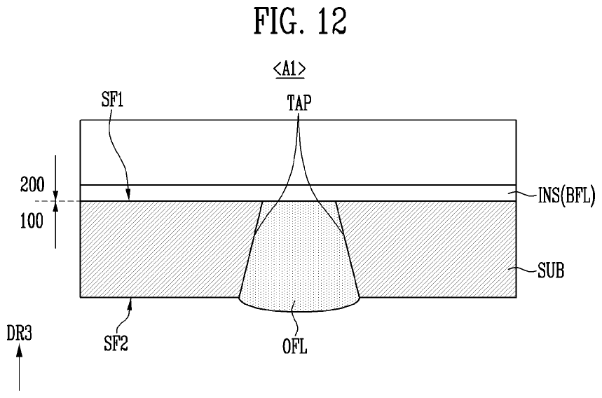

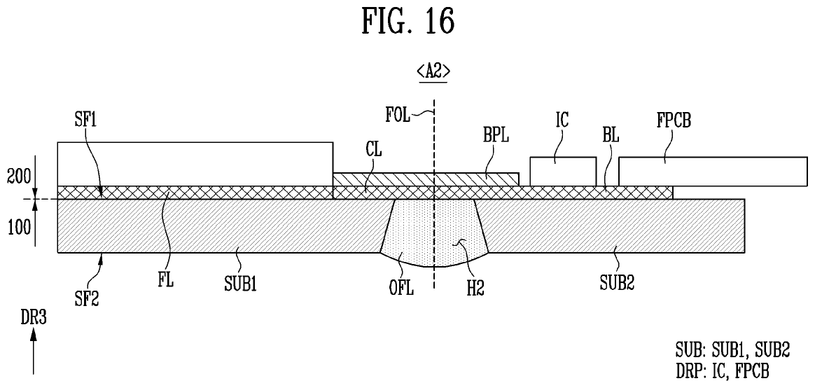

Referring to FIGS. 12 and 16, the organic layer OFL may be disposed in the hole H.

In the present step, the organic layer OFL may be filled in the first hole H1 in the first area A1. As the organic layer OFL is filled, the organic layer OFL and the lowermost insulating layer INS may contact each other in the present step. As described above, an area where the organic layer OFL is filled may correspond to the bending line BEL.

In the present step, the organic layer OFL may be filled in the second hole H2 in the second area A2. Accordingly, each of the first substrate SUB1 and the second substrate SUB2 may directly adjacent to (e.g., contact) the organic layer OFL. However, the disclosure is not limited thereto. For example, the organic layer OFL may not be filled in the second hole H2.

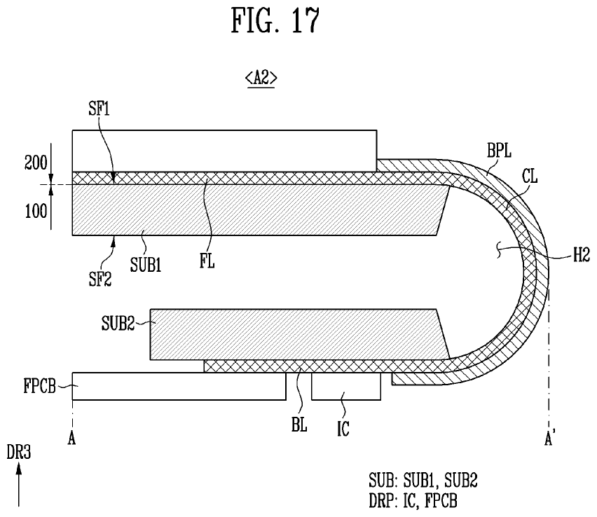

Referring to FIG. 17, in the second area A2, the substrate structure including the first substrate SUB1 and the second substrate SUB2 may be bent along the outer folding line FOL.

In the present step, the connection line CL and the protective layer BPL may be folded. According to an embodiment, the outer folding line FOL where the substrate structure is bent may overlap the area where the second hole H2 is formed.

Meanwhile, as described above, when the organic layer OFL is not filled in the second hole H2, the substrate structure may be bent in a state in which the second hole H2 is open, and when the organic layer OFL is filled in the second hole H2, the substrate structure may be bent in a state in which the organic layer OFL is provided in the second hole H2.

According to an embodiment, after the second hole H2 is formed, as a plurality of layers are bent based on the area where the second hole H2 is formed, structural stability in a folded area may be secured. Accordingly, the display device 1 with improved structural stability may be manufactured while the dead space is reduced by forming the drive circuit unit DRP on the rear surface of the display device 1.

Although the disclosure has been described with reference to the preferred embodiment above, those skilled in the art or those having a common knowledge in the art will understand that the disclosure may be variously modified and changed without departing from the spirit and technical area of the disclosure described in the claims which will be described later.

Therefore, the technical scope of the disclosure should not be limited to the contents described in the detailed description of the specification, but should be defined by the claims.

What is claimed is:

1. A display device comprising:
a substrate layer including a substrate defining a hole therein and an organic layer of which at least a portion is disposed in the hole; and
a display layer on the substrate layer,
wherein the hole passes through the substrate, and the organic layer contacts at least a portion of the display layer.

2. The display device according to claim 1, wherein the display device is foldable or bendable with respect to a bending line, and includes a display area for emitting light and overlapping the bending line, and
the bending line overlaps the organic layer in a plan view.

3. The display device according to claim 1, wherein the substrate has a first thickness, and
the organic layer has a second thickness larger than the first thickness.

4. The display device according to claim 1, wherein the organic layer includes a tapered surface extending in an oblique direction with respect to a major surface of the substrate layer, and
an angle between the tapered surface and the major surface of the display layer is equal to or more than 60 degrees and less than 90 degrees.

5. The display device according to claim 1, wherein the substrate layer includes a first surface adjacent to the display layer and a second surface opposite to the first surface, and
the organic layer includes a first cross-section cut by the first surface and having a first cross-sectional area and a second cross-section cut by the second surface and having a second cross-sectional area larger than the first cross-sectional area.

6. The display device according to claim 1, wherein the display layer includes a lowermost insulating layer directly adjacent to the substrate layer, and
the organic layer and the lowermost insulating layer contact each other in an area where the hole is formed.

7. The display device according to claim 6, wherein the display layer includes a pixel circuit including a transistor and a light emitting element electrically connected to the pixel circuit,
the transistor includes an active layer, a gate electrode overlapping the active layer in a plan view, a source electrode electrically connected to a first contact area of the active layer, and a drain electrode electrically connected to a second contact area of the active layer, and
the lowermost insulating layer is a buffer layer directly adjacent to a lower portion of the active layer.

8. The display device according to claim 6, wherein the organic layer includes an undercut area disposed in an area adjacent to both the lowermost insulating layer and the substrate, and
in the undercut area, the organic layer contacts the lowermost insulating layer, and contacts the substrate.

9. The display device according to claim 8, wherein in the undercut area, the substrate and the lowermost insulating layer form an angle of less than 15 degrees.

10. The display device according to claim 1, comprising:
a display area and a non-display area surrounding at least a portion of the display area; and
a driving chip,
wherein the display layer includes a pixel circuit electrically connected to the driving chip,
the substrate includes a first substrate and a second substrate disposed on a rear surface of the first substrate in the non-display area,
the driving chip is disposed on the rear surface of the first substrate, and
the substrate defines an outer hole between an end of the first substrate and an end of the second substrate.

11. The display device according to claim 10, wherein the second substrate does not overlap the organic layer in a plan view.

12. The display device according to claim 10, further comprising:
an outer organic layer provided in the outer hole.

13. The display device according to claim 1, wherein the substrate includes a glass material, and
the organic layer includes at least one of a group of polyurethane, polyimide, polyethylene, and polypropylene.

14. The display device according to claim 1, further comprising:
an upper layer disposed on the display layer and including a window; and
a lower layer disposed under the substrate layer and including a sensing module.

15. A flexible display device foldable with respect to a bending line, comprising:
a display area and a non-display area surrounding at least a portion of the display area;
a substrate layer including a first substrate defining a first hole therein, a second substrate disposed on a rear surface of the first substrate, and an organic layer of which at least a portion is disposed in the first hole; and
a display layer disposed on the substrate layer and including a light emitting element disposed in the display area,
wherein the organic layer overlaps the bending line in a plan view,
the first substrate and the second substrate overlap in the non-display area in the plan view, and
ends of the first substrate and the second substrate are spaced apart from each other to form a second hole.

16. A method of manufacturing a display device, the method comprising:
disposing a display layer on a first surface of a substrate including the first surface and a second surface opposite to the first surface;
forming a hole passing through the substrate by performing wet etching on at least a portion of the substrate in a direction from the second surface toward the first surface; and
disposing an organic layer in the hole.

17. The method according to claim 16, wherein the display layer includes a lowermost insulating layer,
the forming of the hole includes exposing the lowermost insulating layer, and
the disposing of the organic layer includes contacting the lowermost insulating layer and the organic layer.

18. The method according to claim 16, wherein the forming of the hole includes forming a free-hole structure by performing a laser process on the substrate before the wet etching.

19. The method according to claim 16, further comprising:
disposing a driving circuit unit including a driving chip on the first surface of the substrate;
forming an outer hole passing through the substrate to separate the substrate as a first substrate and a second substrate spaced apart from each other, as a step performed in a same process as the forming of the hole; and
folding a stack structure including the first substrate and the second substrate along an outer folding line overlapping the outer hole.

20. The method according to claim 19, further comprising:
disposing an outer organic layer in the outer hole.
